(19) United States
(12) Patent Application Publication
(10) Pub. No.: US 2026/0027604 A1
(43) Pub. Date: Jan. 29, 2026

(54) SOLAR PANEL RECYCLING MECHANISM

(71) Applicant: Reverse Energy Solutions Corp., Chicago, IL (US)

(72) Inventors: Hsiao-Feng TU, New Taipei (TW); Wen-Chieh LIAO, Taipei (TW)

(21) Appl. No.: 18/907,823

(22) Filed: Oct. 7, 2024

(30) Foreign Application Priority Data
Jul. 29, 2024 (TW) 113128109

(51) Int. Cl. B09B 3/35; B09B 3/32; B09B 101/15; B65G 47/91; H01L 31/18

(52) U.S. Cl. CPC B09B 3/35; B09B 3/32; B65G 47/91; H10F 71/00; B09B 2101/15

(57) ABSTRACT

A solar panel recycling mechanism, which uses a material picking unit to pick up waste solar panels for a frame unloading unit to receive waste solar panels, and uses a robot arm to dismantle the frame of each waste solar panel for a feeding channel to receive each waste solar panel after the frame is removed, so that an inner crushing zone can press the glass panel on each waste solar panel and a discharge port can send each waste solar panel with the removed glass panel to a placement area outside for stacking. A operation unit of a control area controls a power supply unit to provide the material picking unit, frame unloading unit, glass removal unit and placement area with the required power, and also controls the operation of each unit to process waste solar panels, so as to achieve the purpose of quickly dismantling waste solar panels.

This application claims the priority benefit of Taiwan patent application number 113128109, filed on Jul. 29, 2024.

### BACKGROUND OF THE INVENTION

### 1. Field of the Invention

The present invention provides a solar panel recycling mechanism, in particular a recycling mechanism that can automatically recycle waste materials of preset solar panels. Through the material picking unit, frame unloading unit, glass removal unit, placement area and control area, the preset waste materials are disassembled and processed one by one, achieving the purpose of automated and consistent operation to process the preset waste materials.

### 2. Description of the Related Art

As domestic electricity consumption continues to increase and power supply becomes very tight, many companies, factories, or homes will install solar panels to store electricity to provide part of the required electricity. The solar power generation collects heat energy from sunlight through solar panels and converts it into electrical energy to meet various power needs. The solar panels generally used are composed mainly of a solar cell module sandwiched between two layers of ethylene vinyl acetate (EVA), and then encapsulated with a glass panel and an insulating backplane to form a layered composite structure. However, the solar panels are usually installed on a certain scale and the number of solar panels used is also considerable. However, the solar panels have a certain lifespan. When they can no longer be used, they must be discarded and new solar panels must be installed to generate electricity. As for discarded solar panels, they need to be recycled and processed to avoid pollution or damage to the environment.

Currently, the recycling of discarded solar panels mostly adopts methods such as thermal cracking, hot knife, chemical treatment, laser or incineration, etc. Usually, the frame of the solar panel is dismantled first, the glass on the solar panel is crushed, and the electronic products are recycled. Then, different waste materials such as glass, metal or plastic are broken into small pieces by mechanical crushing before further processing. However, the solar panels are large in size and heavy in weight, and both assembly and disassembly are time-consuming and labor-intensive. After they are discarded, the processing of various types of discarded solar panels must be carried out separately and in batches. The handling, transfer, stacking or storage of waste materials during the process also causes considerable trouble and is likely to cause harm to the safety of workers. Not only does it require a large amount of manpower to carry out the processing operations, but it also requires larger and more space for various processing operations to be implemented and executed. The waste materials treatment process is extremely time-consuming and labor-intensive, and is not economical. There are many deficiencies that need to be improved.

### SUMMARY OF THE INVENTION

Therefore, in view of the above problems and deficiencies, the inventor collected relevant information, evaluated and considered various aspects, and used his many years of experience in this industry to continuously create, research and improve, and finally designed the invention patent of this solar panel recycling mechanism.

The main object of the present invention is that a material picking seat movably provided at a transfer track of a material picking unit has a plurality of material picking suction cups, and is used to obtain the preset waste material, which can be received by a frame unloading unit through a feeding belt; a robot arm is used to dismantle the frame of the preset waste material; a feeding channel in alignment with a glass removal unit at the terminal receives the preset waste material after the frame is removed; a crushing zone on the inner side of the feeding channel presses the glass panel on the surface of the preset waste material after the frame is removed; a discharge port on the other side of the crushing zone sends the preset waste material with the removed glass panel to a supporting base of a placement area outside for stacking; a operation unit of a control area controls a power supply unit to provide the material picking unit, the frame unloading unit, the glass removal unit and the placement area with the required power, and also controls the operation of each unit to process the preset waste material, so as to achieve the purpose of quickly dismantling the preset waste material and save time and labor.

Another object of the present invention is that the recycling mechanism further includes a mobile device for loading the material picking unit, the frame unloading unit, the glass removal unit, the placement area and the control area, and the mobile device is a truck or a trolley.

Still another object of the present invention is that the transfer track of the material picking unit is controlled by the operation unit of the control area to be extended and retracted, and the material picking seat at the transfer track can slide along the transfer track and move in and out of the interior or exterior of the material picking unit; the plurality of material picking suction cups on the material picking seat may be vacuum suction cups, silicone suction cups, rubber suction cups, robot suction cups, micro suction cups, sponge suction cups, anti-static suction cups (ESD) or conductive suction cups, for absorbing the preset waste material, and the preset waste material may be discarded or faulty solar panels to be recycled.

Still another object of the present invention is that the feeding belt of the frame unloading unit can be a plurality of rollers or a roller and conveyor belt type, so that the preset waste material can be transported by the feeding belt.

Still another object of the present invention is that the glass removal unit further comprises a plurality of extrusion wheel cutters, a plurality of driving rods located in the crushing zone, at least one motor for driving the plurality of driving rods to abut the preset waste material and the plurality of said extrusion wheel cutters to press the glass panel on the surface of the preset waste material to form a plurality of glass fragments, and at least one collecting area provided below the plurality of extrusion wheel cutters for collecting the plurality of glass fragments pressed by the plurality of extrusion wheel cutters; and the driving rods are driven by at least one motor to rotate axially and move vertically, so as to collect the plurality of glass fragments after compression at at least one collecting area, and carry out related subsequent processing, recycling and reuse operations.

### BRIEF DESCRIPTION OF THE DRAWINGS

FIG. 1 is a three-dimensional external view of the present invention.

FIG. 2 is a side view of the present invention.

FIG. 3 is a three-dimensional external view of the glass removal unit of the present invention.

### DETAILED DESCRIPTION OF THE INVENTION

In order to achieve the above-mentioned objects and effect, the technical means and structure, implementation method, etc. adopted by the present invention are described in detail with reference to the preferred embodiment of the present invention, and its features and functions are as follows, so as to facilitate a complete understanding.

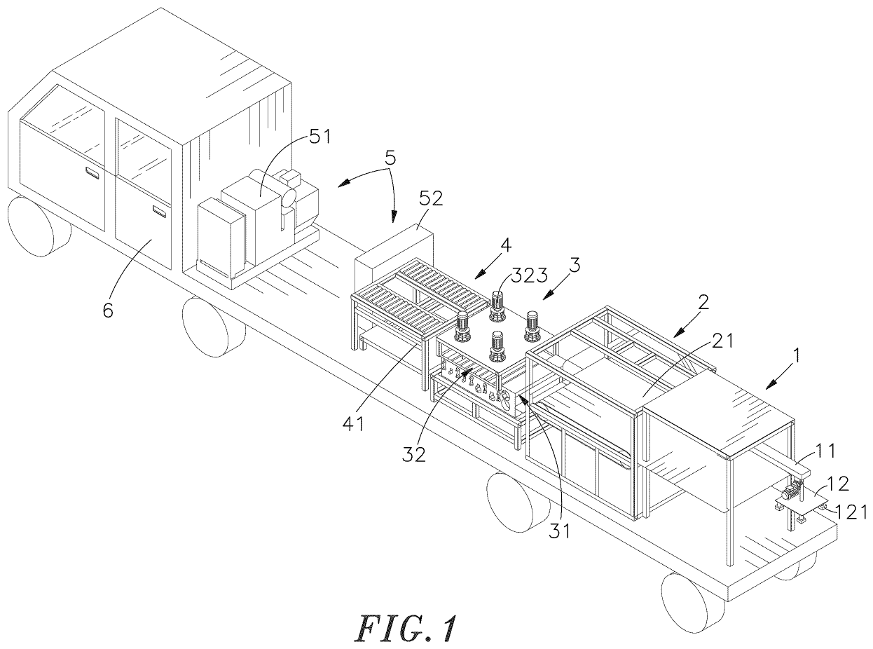

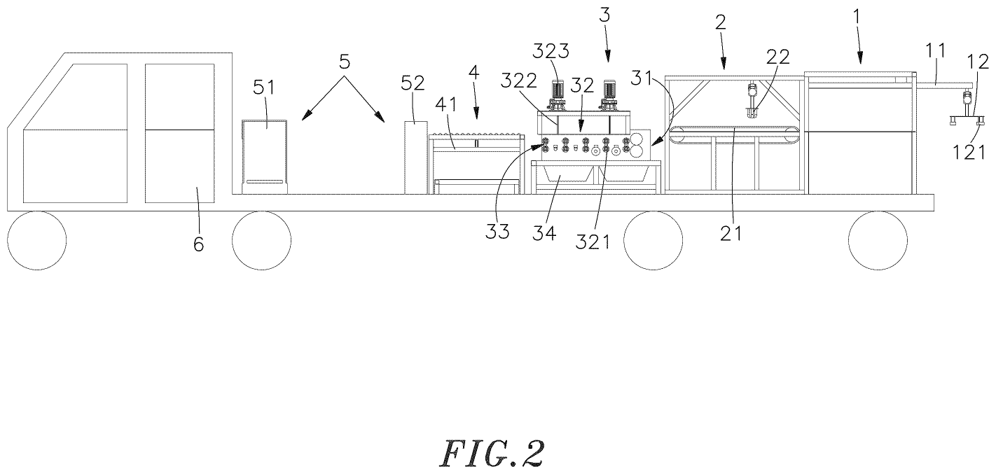

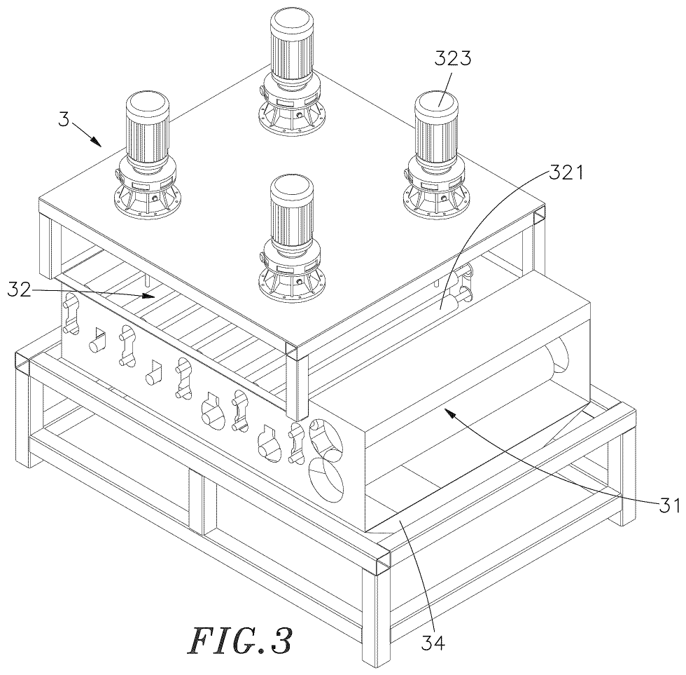

Please refer to FIGS. 1 to 3. The solar panel recycling mechanism of the present invention comprises a material picking unit 1, a frame unloading unit 2, a glass removal unit 3, a placement area 4 and a control area 5.

The material picking unit 1 comprises a transfer track 11, a material picking seat 12 movably disposed at the transfer track 11, and a plurality of material picking suction cups 121 disposed on the material picking seat 12 for picking up a preset waste material.

The frame unloading unit 2 comprises a feeding belt 21 for receiving the preset waste material taken from the material picking unit 1, and a robot arm 22 provided around the feeding belt 21 for disassembling the frame of the preset waste material (The detailed frame disassembly operation is not described in detail because it is not the focus of the invention).

The glass removal unit 3 comprises a feeding channel 31 located at the end of the feeding belt 21 to receive the preset waste material after the frame unloading, a crushing zone 32 provided inside the feeding channel 31 to compress the glass panel on the surface of the preset waste material after the frame unloading, and a discharge port 33 provided on the other side of the crushing zone 32 relative to the feeding channel 31, through which the preset waste material with the removed glass panel can be discharged.

The placement area 4 is located outside the discharge port 33 of the glass removal unit 3 and is provided with a supporting base 41 for stacking and placing the preset waste material.

The control area 5 comprises a power supply unit 51 and an operation unit 52. The power supply unit 51 can provide the power required by the material picking unit 1, the frame unloading unit 2, the glass removal unit 3 and the placement area 4. Then, the operation unit 52 controls the power supply unit 51, the material picking unit 1, the frame unloading unit 2, the glass removal unit 3 and the placement area 4 to perform various processing operations on the preset waste material.

The recycling mechanism of the present invention may further comprise a mobile device 6, and the mobile device 6 may be a truck or a trolley, etc., and the material picking unit 1, the frame unloading unit 2, the glass removal unit 3, the placement area 4 and the control area 5 may be assembled on the mobile device 6 in sequence.

The transfer track 11 of the above-mentioned material picking unit 1 of the present invention is controlled by the operation unit 52 of the control area 5 to perform telescopic movement, and the material picking seat 12 at the transfer track 11 can slide along the transfer track 11 and move in and out of the interior or exterior of the material picking unit 1. The plurality of material picking suction cups 121 on the material picking seat 12 may be vacuum suction cups, silicone suction cups, rubber suction cups, robot suction cups, micro suction cups, sponge suction cups, anti-static suction cups (ESD) or conductive suction cups, etc., for sucking up the preset waste material to be recycled, and the preset waste material may be a waste or faulty solar panel to be recycled.

In addition, the feeding belt 21 of the above-mentioned frame unloading unit 2 of the present invention can be a multiple roller type or a roller and conveyor belt type, so that the preset waste material is transported by the feeding belt 21.

Furthermore, the above-mentioned glass removal unit 3 of the present invention further comprises a plurality of extrusion wheel cutters 321, a plurality of driving rods 322 located in the crushing zone 32, at least one motor 323 for driving the plurality of driving rods 322 to abut the preset waste material and the plurality of extrusion wheel cutters 321 to press the glass panel on the surface of the preset waste material to form a plurality of glass fragments, and at least one collecting area 34 provided below the plurality of extrusion wheel cutters 321 for collecting the plurality of glass fragments pressed by the plurality of extrusion wheel cutters 321. The driving rods 322 are driven by at least one motor 323 to rotate axially and move vertically, so that the plurality of glass fragments after compression can be collected at the collecting area 34, and related subsequent processing, recycling and reuse operations can further be performed.

When the above-mentioned solar panel recycling mechanism of the present invention is actually applied and implemented, the recycling mechanism can be transported to a predetermined location for collecting solar panel waste materials via the mobile device 6. First, the operation unit 52 of the control area 5 is used to control the transfer track 11 of the material picking unit 1 to transfer the material picking seat 12 to the location where the preset waste material is to be recycled. The operation unit 52 then operates the material picking seat 12 to suck the preset waste material with the plurality of material picking suction cups 121. The operation unit 52 then drives the transfer track 11 to drive the material picking seat 12 to transfer the preset waste material to the feeding belt 21 of the frame unloading unit 2. Then, the operation unit 52 controls the robot arm 22 of the frame unloading unit 2 to dismantle and remove the frame of the preset waste material on the feeding belt 21. After the frame of the preset waste material is unloaded, the operation unit 52 drives the feeding belt 21 to transport the preset waste material with the removed frame to the glass removal unit 3 and enter the crushing zone 32 through the feeding channel 31. The plurality of driving rods 322 push the preset waste material to the plurality of extrusion wheel cutters 321, so that the glass panel on the surface of the preset waste material is squeezed and compressed by the plurality of extrusion wheel cutters 321, and the glass panel is broken into the plurality of glass fragments, then the plurality of glass fragments fall into at least one collecting area 34 below. In addition, after the glass panel on the surface of the preset waste material is removed, the remaining internal solar cells and related electronic products can be sent from the discharge port 33 to the supporting base 41 of the placement area 4 to be stacked one by one. After being stacked to a predetermined amount, the preset waste material can be removed from the supporting base 41 and transferred to subsequent solar cells and related electronic products handling operations, thereby achieving the purpose of uniform processing, rapid disassembly and separation of the preset solar panel waste materials. It saves time and labor, is more economical, and helps to handle a large number of waste materials from preset solar panels.

The above are merely preferred embodiments of the present invention and are not intended to limit the patent scope of the present invention. Therefore, all simple modifications and equivalent structural changes made by using the contents of the description and drawings of the present invention should be included in the patent scope of the present invention and should be declared.

In summary, the solar panel recycling mechanism of the present invention can truly achieve its effect and purpose when it is actually applied. Therefore, this invention is truly a research and development creation with excellent practicality. In order to meet the application requirements for invention patents, an application is filed in accordance with the law. I hope that the review committee will approve this case as soon as possible to protect the inventor's hard work in research and development. If the review committee has any questions, please feel free to write to us for instructions. The inventor will do his best to cooperate and will be very grateful.

What is claimed is:

1. A solar panel recycling mechanism, comprising:
a material picking unit comprises a transfer track, a material picking seat movably disposed at said transfer track, and a plurality of material picking suction cups disposed on said material picking seat for picking up a preset waste material;
a frame unloading unit comprises a feeding belt for receiving the preset waste material taken from said material picking unit, and a robot arm provided around said feeding belt for disassembling a frame of the preset waste material;
a glass removal unit comprises a feeding channel located at one end of said feeding belt to receive the preset waste material after the frame unloading, a crushing zone provided inside said feeding channel to compress a glass panel on the surface of the preset waste material after the frame unloading, and a discharge port provided on the other side of said crushing zone relative to said feeding channel for discharging the preset waste material with the removed glass panel;
a placement area located outside said discharge port of said glass removal unit, said placement area being provided with a supporting base for stacking and placing the preset waste material; and
a control area comprises a power supply unit and an operation unit, said power supply unit providing the power required by said material picking unit, said frame unloading unit, said glass removal unit and said placement area, said operation unit controlling said power supply unit, said material picking unit, said frame unloading unit, said glass removal unit and said placement area to perform various processing operations on the preset waste material.

2. The solar panel recycling mechanism as claimed in claim 1, wherein the recycling mechanism further comprising a mobile device for loading said material picking unit, said frame unloading unit, said glass removal unit, said placement area and said control area, and said mobile device being selectively a truck or a trolley.

3. The solar panel recycling mechanism as claimed in claim 1, wherein said transfer track of said material picking unit is controlled by said operation unit of said control area to perform extension and retraction movement, and allows said material picking seat at said transfer track to slide along said transfer track and move in and out of the interior or exterior of said material picking unit; the plurality of said material picking suction cups on said material picking seat are selectively vacuum suction cups, silicone suction cups, rubber suction cups, robot suction cups, micro suction cups, sponge suction cups, anti-static suction cups (ESD) or conductive suction cups for obtaining the preset waste material, and the preset waste materials is a discarded or faulty solar panel to be recycled.

4. The solar panel recycling mechanism as claimed in claim 1, wherein said feeding belt of said frame unloading unit is selectively a multiple roller type feeding belt or a roller and conveyor belt type feeding belt.

5. The solar panel recycling mechanism as claimed in claim 1, wherein said glass removal unit further comprising a plurality of extrusion wheel cutters, a plurality of driving rods located in said crushing zone, at least one motor for driving the plurality of said driving rods to abut the preset waste material and the plurality of said extrusion wheel cutters to press the glass panel on the surface of said preset waste material to form a plurality of glass fragments, and at least one collecting area provided below the plurality of said extrusion wheel cutters for collecting the plurality of glass fragments pressed by the plurality of said extrusion wheel cutters; said driving rods are driven by at least one said motor to rotate axially and move vertically.
